(19) United States
(12) Patent Application Publication
(10) Pub. No.: US 2010/0018581 A1
(43) Pub. Date: Jan. 28, 2010

(54) LARGE AREA SOLAR CELL

(75) Inventors: Vishal Shrotriya, El Monte, CA (US); Casey Irvin, El Monte, CA (US); Gang Li, El Monte, CA (US); Yang Yang, Los Angeles, CA (US)

Correspondence Address: GREENBERG TRAURIG LLP (LA), 2450 COLORADO AVENUE, SUITE 400E, INTELLECTUAL PROPERTY DEPARTMENT, SANTA MONICA, CA, 90404, US

(73) Assignees: SOLARMER ENERGY, INC., El Monte, CA (US); THE REGENTS OF THE UNIVERSITY OF CALIFORNIA, Oakland, CA (US)

(21) Appl. No.: 12/179,387

(22) Filed: Jul. 24, 2008

(51) Int. Cl. H01L 31/0352

(52) U.S. Cl. 136/265; 29/592.1

(57) ABSTRACT

A polymer solar cell has an anode, cathode and an active layer. The anode has a surface area larger than the cathode. On the anode, in the area with no cathode, is a conducting element in electrical contact with the anode, having a higher conductivity than the anode and substantially surrounding the cathode in order to minimize the distance between any two points on the cathode and the conducting element. The conducting element allows electrons to travel a shorter distance in the anode and through a higher conducting path to an electrical contact.

### BACKGROUND

1. Field

This disclosure relates, in general, to solar cells and more particularly to organic solar cells.

2. General Background

As the area of a polymer solar cell increases, the series resistance to the flow of electrons increases and, subsequently, the cells' performance (PCE %) decreases. This decrease is due to the relatively poor conductivity of materials used when fabricating the anodes of polymer solar cells compared to the anodes of their non-polymer counterparts.

It is, therefore, an object of the present disclosure to provide a conduit for the unobstructed flow of electrons to charge collection contacts.

### SUMMARY

In one aspect of the present disclosure, there is an anode for a solar cell, provided as a layer, on a substrate. Stacked on top of the anode are an active layer and a cathode.

The anode is larger in surface area than the area of the cathode. A conducting element in electrical contact with the anode is provided on the area of the anode that is not occupied by the cathode.

The conducting element has a higher conductivity than the anode and substantially surrounds the cathode in order to minimize the distance between any two points on the cathode and the conducting element. The conducting element allows electrons to travel a shorter distance in the anode and through a higher conducting path to the electrical contact instead of traveling the whole distance through a lower conducting medium to the electrical contact.

### DRAWINGS

FIG. 1 is a top view of a solar cell in accordance with an embodiment of the present disclosure.

FIG. 2 illustrates a series of current-voltage curves for a solar cell in accordance with an embodiment of the present disclosure.

FIG. 3 is a cross section view of a solar cell in accordance with an embodiment of the present disclosure.

FIG. 4 is a top view of a solar cell in accordance with an embodiment of the present disclosure.

FIG. 5 is a top view of a solar cell without a conducting element in accordance with an embodiment of the present disclosure.

FIG. 6 is a top view of a solar cell in accordance with an embodiment of the present disclosure.

FIG. 7 is a top view of a plurality of solar cells connected in accordance with an embodiment of the present disclosure.

FIG. 8 is a top view of a solar cell in accordance with an embodiment of the present disclosure.

While the specification concludes with claims defining the features of the present disclosure that are regarded as novel, it is believed that the present disclosure's teachings will be better understood from a consideration of the following description in conjunction with the drawing figures, in which like reference numerals are carried forward.

### DETAILED DESCRIPTION

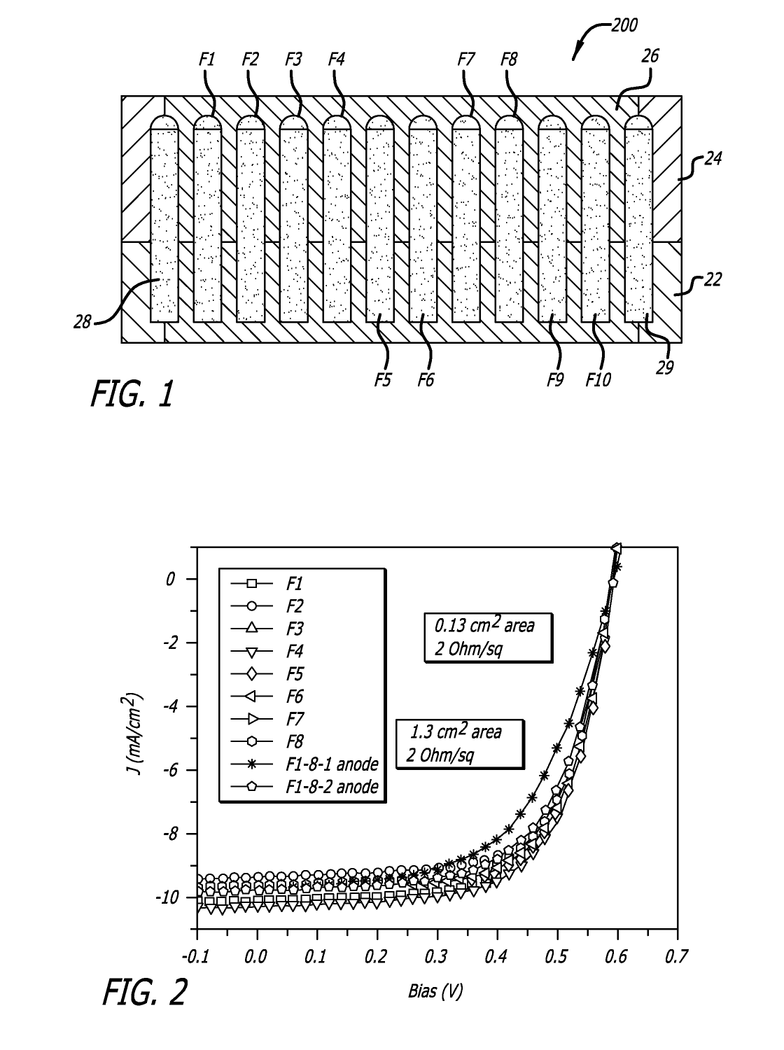

Referring to FIG. 1, there is a solar cell 200 in accordance with one embodiment of the present disclosure. The solar cell 200 has an active layer 26, which absorbs sunlight and converts it into electricity. The active layer 26 is located between electrodes F1-F10 and 22 that are stacked on a mechanically stable substrate and there are anode fingers 28 and 29 in direct electrical contact with the electrode 22.

Referring to FIG. 2, there are current-voltage curves for the solar cell 200 shown in FIG. 1. The first eight curves are for isolated electrodes F1 through F8 while only utilizing anode 28 as the positive contact. The photocurrent (9.3±0.3 mA/cm2) and Voc were kept substantially the same. As the distance from the anode 28 increases, the fill-factor of the solar cell 200 reduces from 66.4% in the first electrode F1 to 65.4% in the eighth electrode F8. The J-V curves indicate a varied series resistance between the different electrodes F1 through F8 in the range of 10 to 50 Ohm and the resistance along electrode's length only slightly affects the electrode's performance. However, when the area of the solar cell 200 is increased by connecting the electrodes F1 through F8 in parallel (for example, an area of about 1.04 cm2) a significant reduction in the fill-factor is observed. The fill-factor is reduced to 57% with substantially the same current. By using more than one anode, such as anode 29 in addition to anode 28, the series resistance is reduced, resulting in a fill-factor of 62% and an overall PCE of 3.61%.

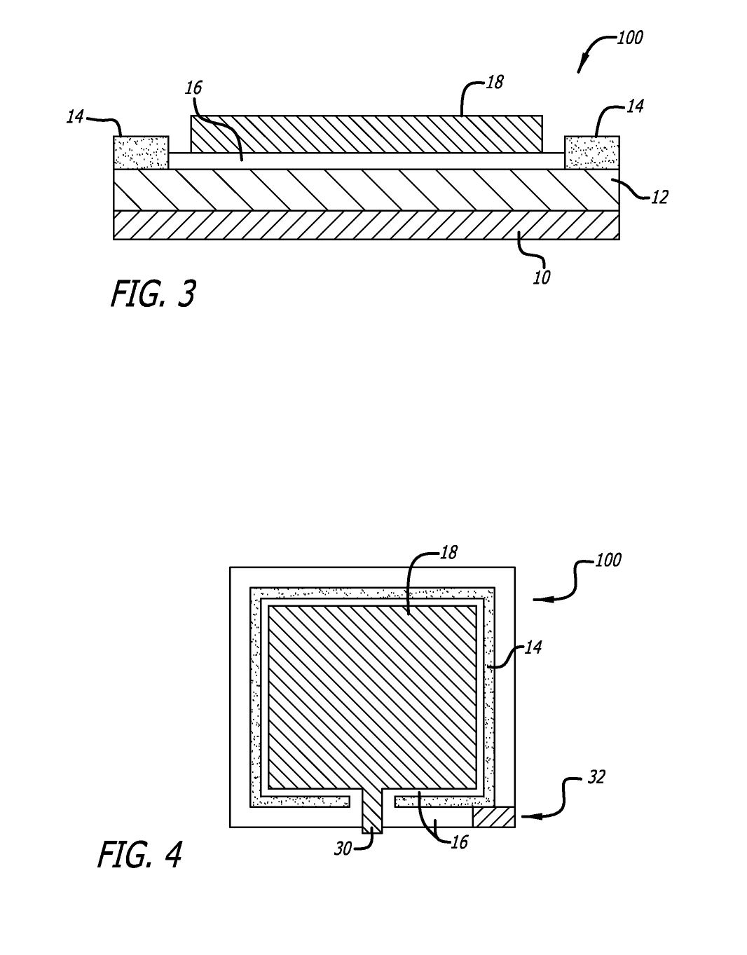

Referring to FIGS. 3-8, a polymer solar cell 100 has a cross section structure shown in FIG. 3. The structure is comprised of an active layer 16, which absorbs sunlight and converts it into electricity. The active layer 16 is located between two electrodes 12 and 18 stacked on a substrate 10. On top of the electrode 12 or anode is a conducting element 14 in electrical contact with the anode 12.

The terms “electrode” and “contact” refer only to layers that provide a medium for delivering photogenerated power to an external circuit or providing a bias voltage to a device such as polymer solar cell 100. That is, an electrode, or contact, provides the interface between the photoconductively active region of an organic photosensitive optoelectronic device and a wire, lead, trace or other means for transporting the charge carriers to or from an external circuit.

The anode 12 is a transparent conductive oxide (TCO), such as indium tin oxide (ITO), fluorinated tin oxide (FTO), aluminum doped zinc oxide (AZO), or carbon nanotubes (CNTs) or high conductivity polymer, that is deposited on the substrate 10. The substrate 10 can either be plastic or glass. The anode 12 layer is obtained by solution processing, sputtering or thermal spray-coating. To enhance cell performance, the substrate 10 and anode 12 are coated with a thin layer of high conductivity polymer, such as poly(ethylenedioxythiophene):poly(styrenesulfonate) (PEDOT:PSS), or polyaniline (PANI).

In a variation, the anode 12 will be covered with a thin layer of transition metal oxides (TMOs), such as vanadium pentoxide (V₂O₅), molybdenum oxide (MoO₃), or tungsten oxide (WO₃). In this variation, the metal oxides are either thermally evaporated or deposited through solution processes directly on top of TCO glass substrates to form the anodic interfacial layer. The TMO layer, with a thickness of 3-20 nm, can replace PEDOT:PSS in the polymer solar cells without affecting the performance since it is transparent and conductive. The efficiency of polymer solar cells with a TCO/TMO anode is comparable to or may even be better than those with a ITO/PEDOT:PSS anode. Using TMO as the anode 12 also prevents unwanted chemical reactions between the ITO and PEDOT:PSS layers, which can result in performance degradation.

In another variation, metal wires or meshes can be embedded into the anode 12 to provide higher surface conductivity and to increase charge collection efficiency. The metal lines can be thermally evaporated on top of the substrate 10 though a photo-mask prepared by photo-lithography. Several high conductivity metals such as aluminum (Al), gold (Au), silver (Ag), copper (Cu), chromium (Cr) coated with Au, and others known in the art can be used for metal lines.

The active layer 16 is typically a bulk-hetero-junction (BHJ) of a p-type donor polymer and an n-type acceptor material. Electron excitons are generated upon photo-absorption and are absorbed into the donor polymer. The excitons migrate to the donor-acceptor interface, are dissociated into free electrons and holes, and are transported through a 3-dimensional (3-D) interpenetrated network of donors and acceptors in the BHJ film to the contacts for charge collection.

The active layer 16 can also be a bi-layer structure consisting of a p-type donor polymer and an n-type acceptor material stacked on top of each other.

The active layer 16 can also consist of multiple layers of BHJ in a tandem configuration, where each BHJ layer contains a p-type donor polymer and an n-type acceptor material, which may or may not be different. These BHJ layers may be separated by a connecting layer such as those used in typical tandem cell structures.

There are many polymers that can be used as a donor material in the BHJ film. A few examples of such donors are P3HT, poly[2-methoxy-5-(3,7-dimethyloctyloxy)-1,4-phenylene vinylene] (MDMO-PPV), or poly(2-methoxy-5-(2′-ethyl-hexyloxy)-1,4-phenylene vinylene) (MEH-PPV). Other low-band-gap polymers may also be utilized.

A few common candidates for the acceptor materials are PCBM or [6,6]-phenyl C₇₁-butyric acid methyl ester (C₇₀-PCBM). Other materials such as single-walled carbon nanotubes (CNTs) and other n-type polymers can also be used.

The active layer 16 can be obtained by spin-coating from polymer solution in organic solvent(s). The film can also be obtained by several other solution processing techniques, such as bar-coating, inkjet-printing, doctor-blading, spray coating, screen printing and others known to those skilled in the art.

To improve the photovoltaic conversion efficiency, the BHJ film may undergo a few treatments. For example, when using a P3HT:PCBM active layer, both solvent annealing and thermal annealing can be used. In the “solvent annealing” approach, the slow solidification rate of the active layer allows the P3HT polymer chains to be organized into a highly ordered crystalline state, which improves the absorption of light within the polymer, enhances the charge carrier mobility, improves the exciton generation and dissociation efficiency, and results in a highly balanced charge carrier transport. These characteristics provide enhanced efficiency.

Thermal annealing has also been used to partially recover polymer crystallinity that also improves cell performance.

Other approaches can include solvent mixing, where two or more solvents are used to dissolve a polymer, adding an ionic salt into the active layer 16, as well as other potential interfacial layer modifications known to those skilled in the art.

In the instant embodiment, the cathode 18 is a metal, such as aluminum, and is provided as a layer on top of the active layer 16. The cathode 18 can be any conducting metal known to those skilled in the art and is designed with the intent of maximizing a ratio of cathode area to non-cathode area in order to maximize the area of the solar cell. The cathode 18 is provided on the active layer 16 and can occupy an area on the active layer 16 that is less than the area of the anode 12.

The materials used to make the anode 12 are not as conductive as their inorganic counterparts. This difference in conductivity becomes particularly pronounced as the surface area of the anode 12 increases, resulting in a decrease in cell performance (PCE %). This decrease in performance is largely due to the series resistance of electron flow through the anode 12 and is reflected as a decrease in the cell's fill factor or the ratio of the actual maximum obtainable power to the theoretically determined power.

In order to overcome the conductive deficiency of the anode 12, a conducting element 14 is provided. The conducting element 14 has a higher conductivity than the anode 12 and, preferably, substantially surrounds the cathode 18 to minimize the series resistance of electrons as they make their way through the anode 12 to the external circuit.

The conducting element 14 allows the electrons to travel a shorter distance through a relatively lower conducting medium (anode 12) and to travel the longer distance through a higher conducting medium (conducting element 14) to the charge collection contact 30, thus increasing the overall charge collection efficiency.

Typically, the active area or the cell area of the solar cell 100 is defined by the area of the cathode 18. Even though the anode 12 and active layer 16 may extend beyond the area of the cathode 18, the anode 12 and active layer 16 are not able to dissociate the charge without the cathode 18 and, thus, this area is inactive.

The conducting element 14 is positioned in this inactive area relative to the cathode 16 and is in electrical contact with the anode 12. Preferably, the conducting element 14 is as close as possible to the cathode 18 while remaining electrically apart. This close distance is preferable because, in order to reduce the series resistance, the distance between any point on the anode 12 to a point on the conducting element 14 must be minimized.

In an effort to further reduce the series resistance through the anode 12, the conducting element 14 configuration shown in FIG. 4 was proposed. FIG. 4 is a top view of the solar cell 100 whose cross section has already been described above and illustrated in FIG. 3. The conducting element 14 substantially surrounds the cathode 18 and is positioned to minimize the distance between a point on the cathode 18 and the conducting element 14.

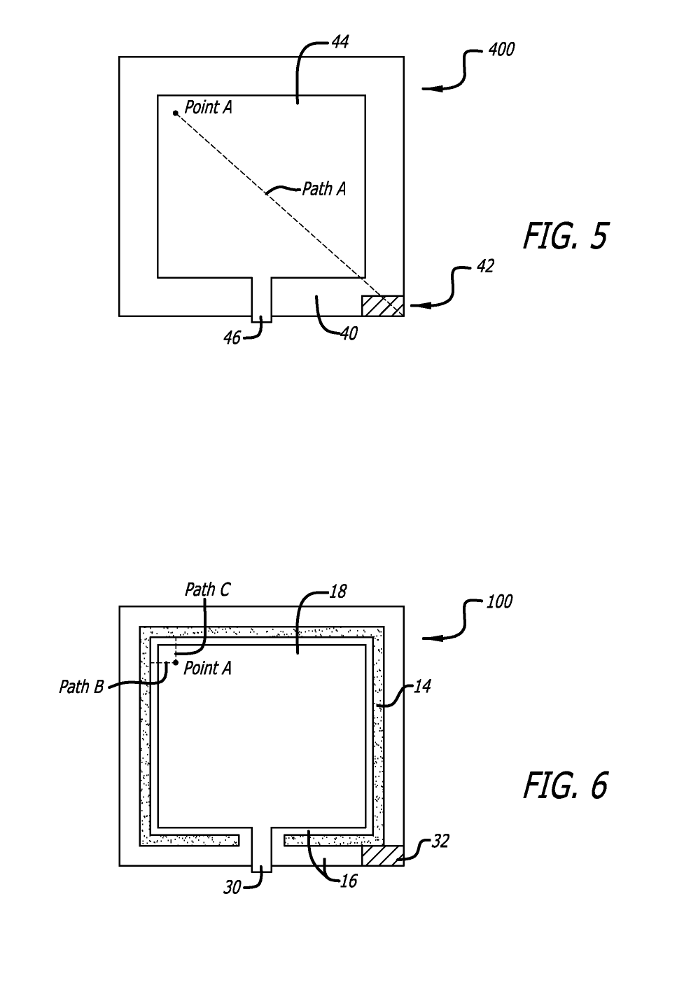

FIG. 5 shows a solar cell 400 that does not utilize the conducting element 14. The solar cell 400 has a substrate and an anode. The anode is provided as a layer on top of the substrate; neither the substrate nor the anode are shown in FIG. 5. The solar cell 400 has an active layer 40 and cathode 44. The cathode 44 also includes a tab 46 and a contact 42 for connecting a lead or wire to the solar cell 400 for connecting the solar cell 400 to an external circuit.

As an example, an electron at Point A of solar cell 400 must travel a distance from Path A to the contact 42. This distance is traveled entirely through the anode.

Solar cell 100 is shown again in FIG. 6 with a corresponding Point A, but includes conducting element 14. The electron at Point A of solar cell 100 will follow a path of least resistance and take either Path B or Path C to and through the conducting element 14 to the contact 32. Paths B and C are much shorter distances for the electron to travel than Path A, through the relatively less conductive anode. Thus, reducing the series resistance results in solar cell 100 having a higher fill factor than solar cell 400.

The conducting element 14 is fused to the anode 12 such that the entire conducting element 14 is substantially in contact with the anode 12. This may be achieved by masking the surface of the anode 12 to apply the active layer 16 and cathode 18. An additional mask may be provided to isolate the cathode 18 when the conducting element 14 is applied.

In one instance, the conducting element 14 is made of the same conductive metal as the cathode 18, allowing the cathode 18 and conducting element 14 to be applied at the same time via masking.

The conductive metals used for the cathode 18 and/or the conducting element 14 can be aluminum, gold, silver, copper, platinum, any other conducting metal or metal combination known by those skilled in the art.

In other instances, the conducting element 14 can be positioned relative to the cathode 18 in any number of spatial relationships or geometric patterns that can minimize the distance between a point on the conducting element 14 and a point on the cathode 18. FIG. 4 is an example of such a spatial relationship. In this instance, the conducting element 14 can be referred to as a surround anode because its spatial relationship is one that substantially surrounds the cathode 18.

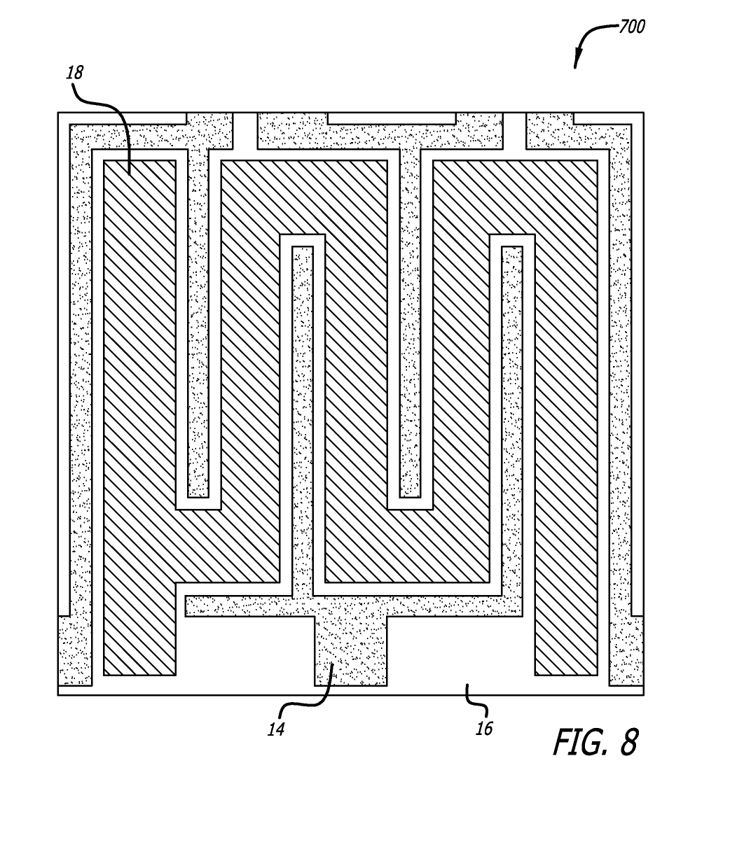

In another instance, illustrated in FIG. 8, solar cell 700 has a zigzag pattern. The cathode 18 and the conducting element 14 weave in and out of each other. The design of solar cell 700 allows for the cathode 18 to be scaled up to surface area sizes previously considered inefficient due to sheet series resistance of the anode.

In one instance, the strength of the ITO anode 12 provides for a method of configuring the conducting element 14 on the anode 12. The active layer 16 is provided as a coating on top of the anode 12 and, thus, either an area of the active layer 16 needs to me masked off, leaving a portion of the anode 12 exposed to apply the conducting element 14, or the active layer 16 needs to be removed. The conducting element 14 must be in electrical contact with the anode 12, and thus requires that a region of the active layer 16 be sufficiently removed for its application. Due to the strength of the ITO anode 12, the active layer 16 can be scraped off the surface of the ITO anode 12 with relatively little damage done by laser ablation, chemical etching or mechanical etching. This feature of ITO can be advantageously utilized to fabricate polymer solar cells.

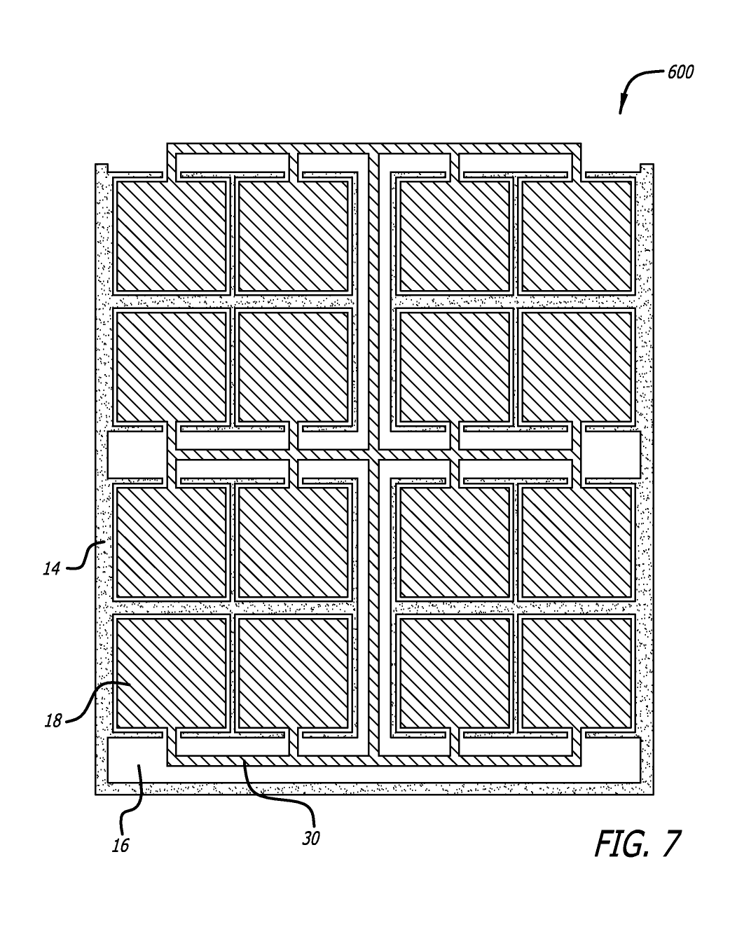

Another important issue for improving the efficiency of large area polymer solar cells is the interconnection of individual solar cells in arrays. Such an array is shown in FIG. 7. Similar device performance degradation also exists in other types of organic electronic devices, e.g. OLEDs for large area lighting applications. Described herein is an example utilizing solar cells, but the strategy is also transferable to other devices.

As described above, the fill factor can be significantly reduced if the resistivity of the conducting electrode is too high when connecting many devices in parallel to try and achieve a solar cell with larger area. As in the example of FIG. 1, it was observed that using the two finger anodes 28-29 at both ends of the ITO covered substrate will improve the fill factor. The two finger anodes 28-29 effectively reduced the carrier transport pass to the collection electrode, which is equivalent to reducing the resistivity.

Expanding this idea, a configuration 600 was proposed in FIG. 7 of individual solar cells 100. The active layer 16 is surrounded by the conducting element 14 to minimize the effective resistance of the solar cell configuration 600. Thus, the solar cell performance is improved (increased fill factor) by decreasing the resistance of the anode, which is achieved by decreasing the distance electrons have to travel, and decreasing the resistivity of these paths.

While the present disclosure has been described in terms of what are presently considered to be the most practical and preferred embodiments, it is to be understood that the disclosure need not be limited to the disclosed embodiments. It is intended to cover various modifications and similar arrangements included within the spirit and scope of the claims, the scope of which should be accorded the broadest interpretation so as to encompass all such modifications and similar structures. The present disclosure includes any and all embodiments of the following claims.

1. An anode for a solar cell comprising:
a conducting element in electrical contact with an anode of a solar cell, wherein the conductive element is positioned relative to a cathode of the solar cell to minimize series resistance of electron flow through the anode.

2. The anode of claim 1, wherein the active layer is on top of the anode and the cathode is on top of the active layer and wherein the conducting element has a higher conductivity than the anode, substantially surrounds the cathode for substantially minimizing a distance between the conducting element and any point within the area of the cathode.

3. The anode of claim 1, wherein the conducting element is provided in electrical contact with the anode such that the entire conducting element is substantially in contact with the anode.

4. The anode of claim 2, wherein the anode is one from the group of indium tin oxide (ITO), fluorinated tin oxide (FTO), aluminum doped zinc oxide (AZO), carbon nanotubes (CNTs) and high conductivity polymer.

5. The anode of claim 1, wherein the cathode and the conducting element are provided in a geometric pattern relative to each other.

6. The anode of claim 5, wherein a ratio of cathode area to non-cathode area is maximized.

7. A method of configuring an anode of a solar cell, the solar cell having a substrate, an anode on the substrate, an active layer, and a cathode, the method comprising:
providing a conducting element in electrical contact with the anode, wherein the conducting element is positioned relative to the cathode and being for minimizing series resistance of electrons through the anode.

8. The method of claim 7, wherein the conducting element has a higher conductivity than the anode and substantially surrounds the cathode for substantially minimizing a distance between the conducting element and any point within the area of the cathode.

9. The method of claim 7, wherein the conducting element is provided in electrical contact with the anode such that the entire conducting element is substantially in contact with the anode.

10. The method of claim 7, wherein the cathode and the conducting element are provided in a geometric pattern relative to each other.

11. The method of claim 10, wherein the ratio of cathode area to non-cathode area is maximized.

12. The method of claim 7, wherein the anode is one from the group of indium tin oxide (ITO), fluorinated tin oxide (FTO), aluminum doped zinc oxide (AZO), carbon nanotubes (CNTs) and high conductivity polymer.

13. A solar cell comprising:
a substrate;
an anode provided on the substrate;
an active layer provided on the anode;
a cathode provided on the active layer, wherein the cathode occupies an area on the active layer that is less than the area of the anode and wherein a conducting element is substantially surrounding the cathode and is in electrical contact with the anode to minimize series resistance of electron flow through the anode.

14. The solar cell of claim 13, wherein the conducting element is separated from the cathode by the active layer and wherein the conducting element substantially surrounds the cathode for substantially minimizing a distance between the conducting element and any point within the area of the cathode.

15. The solar cell of claim 13, wherein the anode is one from the group of indium tin oxide (ITO), fluorinated tin oxide (FTO), aluminum doped zinc oxide (AZO), carbon nanotubes (CNTs) and high conductivity polymer.

16. The solar cell of claim 13, wherein the conducting element is provided in electrical contact with the anode such that the entire conducting element is substantially in contact with the anode.

17. The solar cell of claim 13, wherein the cathode and the conducting element are provided in a geometric pattern relative to each other.

18. The solar cell of claim 16, wherein the ratio of cathode area to non-cathode area is maximized.

19. The solar cell of claim 13, wherein the conducting element has a higher conductivity than the anode.

20. An anode for a solar cell comprising:
a conducting element in electrical contact with an anode of a solar cell, wherein the conducting element has a higher conductivity than the anode and is positioned adjacent to a cathode of the solar cell to minimize series resistance of electron flow through the anode.
